(19) United States
(12) Patent Application Publication
(10) Pub. No.: US 2015/0111324 A1
(43) Pub. Date: Apr. 23, 2015

(54) PACKAGE STRUCTURE OF OPTICAL MODULE

(71) Applicant: LINGSEN PRECISION INDUSTRIES, LTD., TAICHUNG CITY (TW)

(72) Inventors: Ming-Te TU, TAICHUNG CITY (TW); Yao-Ting YEH, TAICHUNG CITY (TW)

(21) Appl. No.: 14/579,686

(22) Filed: Dec. 22, 2014

Related U.S. Application Data
(62) Division of application No. 14/073,400, filed on Nov. 6, 2013.

(30) Foreign Application Priority Data
Jul. 25, 2013 (TW) 102126684

(51) Int. Cl. H01L 31/16; H01L 25/16; H01L 31/18

(52) U.S. Cl. CPC H01L 31/16; H01L 31/18; H01L 25/167
USPC 438/25

(57) ABSTRACT

A package structure of an optical module is provided and includes: a light-emitting chip and a light-admitting chip which are disposed at a light-emitting region and a light-admitting region of a substrate, respectively; two encapsulants for enclosing the light-emitting chip and the light-admitting chip, respectively, and forming hemispherical first and second lens portions above the light-emitting chip and the light-admitting chip, respectively; a cover disposed on the substrate and the encapsulants and having a light-emitting hole and a light-admitting hole, wherein the light-emitting hole and the light-admitting hole are positioned above the light-emitting chip and the light-admitting chip, respectively, and the first and second lens portions are received in the light-emitting hole and the light-admitting hole, respectively. The encapsulants of the optical module package structure can be of unequal curvature as needed to enhance light emission efficiency of the light-emitting chip and enhance reception efficiency of the light-admitting chip.

### CROSS REFERENCE TO RELATED APPLICATIONS

This application is a Divisional of co-pending application Ser. No. 14/073,400, filed on Nov. 6, 2013, for which priority is claimed under 35 U.S.C. §120; and this application claims priority of Application No. 102126684 filed in Taiwan, R.O.C. on Jul. 25, 2013 under 35 U.S.C. §119; the entire contents of all of which are hereby incorporated by reference.

### BACKGROUND OF THE INVENTION

1. Technical Field

The present invention relates to package structures, and more particularly, to a package structure of an optical module.

2. Description of Related Art

At present, an optical proximity sensing module is regarded as a mainstream technology choice for use with the new-generation smart electronic devices (such as smartphones). If the electronic device is brought close to the human ear (for face recognition) or put in a pocket, the optical proximity sensing module will turn off the screen display of the electronic device right away to save power and prevent an inadvertent touch on the screen display, thereby enhancing ease of use. The optical proximity sensing module comprises a light-emitting chip (such as a light-emitting diode, LED) for emitting a light beam which is subsequently reflected off the surface of an object to fall on a light-admitting chip, and eventually the light-admitting chip converts the received light beam into an electronic signal for subsequent processing.

However, the conventional optical proximity sensing module has a drawback. Upon completion of a packaging process, the light beam manifests a great diminution in power after the light beam has reflected off the object. As a result, reception of a light signal by the adjacent light-admitting chip is poor or even impossible, and in consequence signals of the aforesaid smart electronic device cannot be read stably and precisely.

### SUMMARY OF THE INVENTION

It is an objective of the present invention to provide a package structure of an optical module to enhance light emission efficiency of a light-emitting chip effectively and overcome the drawbacks of the light-admitting chip in terms of light signal reception.

In order to achieve the above objective, the present invention provides a package structure of an optical module, comprising a substrate, a light-emitting chip, a light-admitting chip, two encapsulants, and a cover. The substrate is defined with a light-emitting region and a light-admitting region. The light-emitting chip is disposed at the light-emitting region of the substrate. The light-admitting chip is disposed at the light-admitting region of the substrate. The encapsulants enclose the light-emitting chip and the light-admitting chip. The encapsulants form hemispherical first and second lens portions above the light-emitting chip and the light-admitting chip, respectively. The cover is disposed on the substrate and the encapsulants and has a light-emitting hole and a light-admitting hole. The light-emitting hole and the light-admitting hole are positioned above the light-emitting chip and the light-admitting chip, respectively. The first and second lens portions are received in the light-emitting hole and the light-admitting hole, respectively.

The encapsulants and the cover are formed by molding.

The first and second lens portions of the encapsulants are of equal or unequal curvature.

The encapsulants are made of a transparent resin.

The cover is integrally formed as a unitary structure and made of an opaque resin.

The substrate is a non-ceramic substrate made of an organic material, such as Bismaleimide Triazine.

The present invention further provides a method for packaging an optical module. The method comprises the steps of:

(a) defining the light-emitting region and the light-admitting region on the substrate;

(b) connecting electrically a light-emitting chip and a light-admitting chip to the light-emitting region and the light-admitting region of the substrate, respectively;

(c) forming a transparent encapsulant at the light-emitting chip and the light-admitting chip; and

(d) molding an opaque the cover on the encapsulants and the substrate.

The electrical connection step is achieved by a wire bonding process and a die attaching process.

In step (d), the optical module packaged by the step (a) through step (c) is cut or punched.

The encapsulants of the optical module package structure can be of unequal curvature as needed to enhance light emission efficiency of the light-emitting chip and enhance reception efficiency of the light-admitting chip.

To enable persons skilled in the art to gain insight into the framework, features, and objectives of the present invention and implement the present invention accordingly, the present invention is hereunder illustrated with a preferred embodiment and the accompanying drawings and described in detail. However, the description below is merely intended to illustrate the technical solution and features of the present invention and the embodiment thereof. All simple modifications, replacements, or constituent component sparing made, without going against the spirit of the present invention, by persons skilled in the art after understanding the technical solution and features of the present invention should fall within the claims of the present invention.

### BRIEF DESCRIPTION OF THE SEVERAL VIEWS OF THE DRAWINGS

The structure, features, and advantages of the present invention are hereunder illustrated with a preferred embodiment in conjunction with the accompanying drawings, in which:

FIG. 1 is a top view of an optical module package structure according to a preferred embodiment of the present invention;

FIG. 2 is a cross-sectional view of the optical module package structure taken along line 2-2 of FIG. 1 according to the preferred embodiment of the present invention; and

FIG. 3 is a schematic view of the process flow of a packaging method according to the preferred embodiment of the present invention.

### DETAILED DESCRIPTION OF THE EMBODIMENT OF THE INVENTION

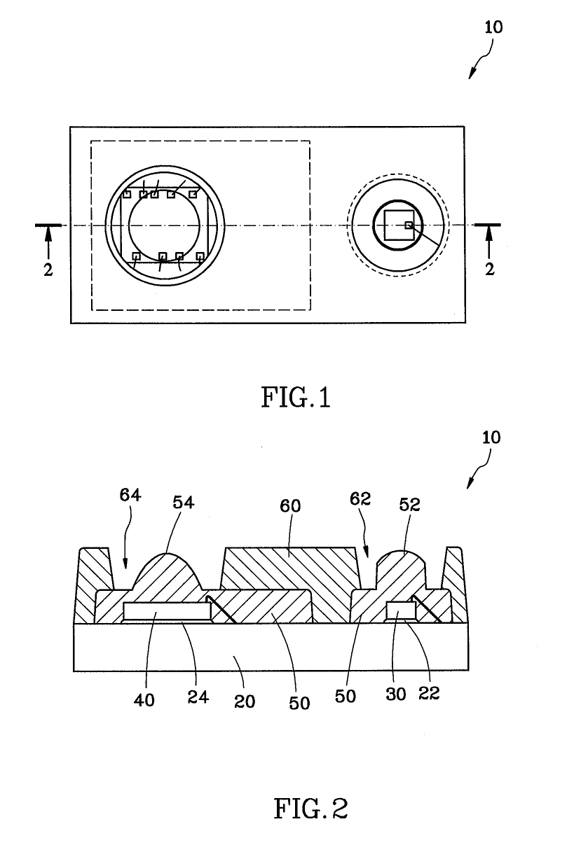

Referring to FIG. 1 through FIG. 3, an optical module package structure 10 provided according to a preferred embodiment of the present invention results from cutting a module from a typical package array and comprises a substrate 20, a light-emitting chip 30, a light-admitting chip 40, two encapsulants 50, and a cover 60.

In this preferred embodiment, the substrate 20 is a substrate made of an organic material, such as Bismaleimide Triazine (BT), or a non-ceramic substrate made from fiberglass reinforced epoxy laminates (commonly known as FR4). Hence, not only is the substrate 20 made of a cheap material, but a light-emitting region 22 and a light-admitting region 24 are also defined on the surface of the substrate 20.

The light-emitting chip 30 and the light-admitting chip 40 undergo a die attaching process and a wire bonding process so as to be disposed at the light-emitting region 22 and the light-admitting region 24 of the substrate 20, respectively. The light-emitting chip 30 emits a light beam. The light-admitting chip 40 receives the light beam emitted from the light-emitting chip 30.

The encapsulants 50 are made of a transparent resin, such as a transparent epoxy resin. The encapsulants 50 enclose the light-emitting chip 30 and the light-admitting chip 40. The encapsulants 50 form hemispherical first and second lens portions 52, 54 above the light-emitting chip 30 and the light-admitting chip 40, respectively.

The cover 60 is integrally formed as a unitary structure and made of an opaque resin, such as an opaque epoxy resin. The cover 60, which is disposed on the substrate 20 and the encapsulants 50, has a light-emitting hole 62 and a light-admitting hole 64. The light-emitting hole 62 and the light-admitting hole 64 are positioned above the light-emitting chip 30 and the light-admitting chip 40, respectively. The first and second lens portions 52, 54 are received in the light-emitting hole 30 and the light-admitting hole 40, respectively. In the preferred embodiment of the present invention, the first and second lens portions 52, 54 are of equal or unequal curvature to thereby meet different usage needs. For example, the larger the curvature of the first lens portion 52 is, the wider is the area illuminated by the light beam emitted from the light-emitting chip 30. The smaller the curvature of the second lens portion 54 is, the more efficient is the second lens portion 54 in focusing the light beam reflected.

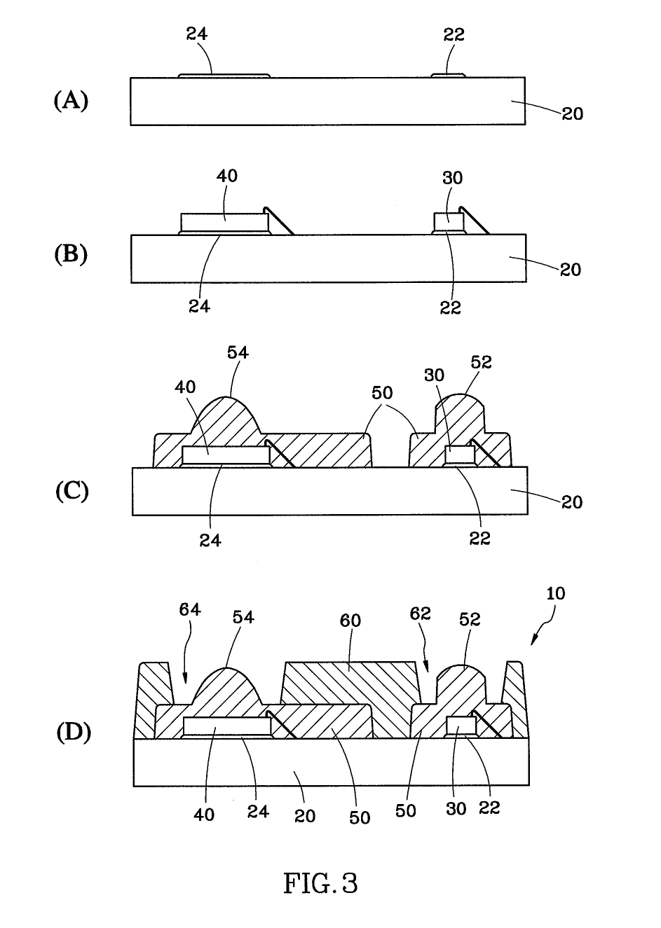

Referring to FIG. 3, A through D, there is shown a schematic view of the process flow of optical module packaging according to the present invention. The first step A involves defining the light-emitting region 22 and the light-admitting region 24 on the single substrate 20 of each substrate array. In the second step B, the light-emitting chip 30 and the light-admitting chip 40 undergo a die attaching process and a wire bonding process so as to be disposed at the light-emitting region 22 and the light-admitting region 24 of the substrate 20, respectively. In the third step C, the transparent encapsulants 50 form hemispherical first and second lens portions 52, 54 above the light-emitting chip 30 and the light-admitting chip 40, respectively, by means of a mold. The fourth step D involves positioning the opaque cover 60 on the substrate 20 and the encapsulants 50 by means of another mold. The cover 60 has the light-emitting hole 62 and the light-admitting hole 64. The light-emitting hole 62 and the light-admitting hole 64 are positioned above the light-emitting chip 30 and the light-admitting chip 40, respectively. The first and second lens portions 52, 54 are received in the light-emitting hole 62 and the light-admitting hole 64, respectively. Hence, not only is the light emission efficiency of the light-emitting chip 30 enhanced effectively, but the drawbacks of the light-admitting chip 40 in terms of light signal reception are also overcome.

In conclusion, the light beam emitted from the light-emitting chip 30 of an optical module according to the present invention passes through the first lens portion 52 of the encapsulant 50, penetrates the light-emitting hole 62 of the cover 60, falls on the surface of an object, reflects off the surface of the object, penetrates the light-admitting hole 64 of the cover 60, and eventually falls on the second lens portion 54 of the encapsulant 50 to focus and reach the light-admitting chip 40, such that the light-admitting chip 40 converts a received light signal into an electronic signal for computation. The present invention is characterized in that, during the process of emitting the light beam and receiving the light beam, the first lens portion 52 of the encapsulant 50 enhances the light emission efficiency of the light beam emitted from the light-emitting chip 30, whereas the second lens portion 54 of the encapsulant 50 enhances the light reception efficiency of the light-admitting chip 40, such that even if the light beam emitted from the light-emitting chip 30 falls on the uneven object surface, the light-admitting chip 40 can still receive the reflected light beam precisely and stably. Constituent elements disclosed in the aforesaid embodiment of the present invention are illustrative rather than restrictive of the present invention. The replacements or changes of other equivalent elements should still fall within the appended claims of the present invention.

What is claimed is:

1. A method for packaging an optical module, the method comprising the steps of:
(a) defining a light-emitting region and a light-admitting region on a substrate;
(b) connecting electrically a light-emitting chip and a light-admitting chip to the light-emitting region and the light-admitting region of the substrate, respectively;
(c) forming a transparent encapsulant at the light-emitting chip and the light-admitting chip; and
(d) molding an opaque the cover on the encapsulants and the substrate.

2. The method of claim 1, wherein the electrical connection step is achieved by a wire bonding process and a die attaching process.

3. The method of claim 1, wherein, in step (d), the optical module packaged by the step (a) through step (c) is cut or punched.
